(19) United States
(12) Patent Application Publication
(10) Pub. No.: US 2021/0053181 A1
(43) Pub. Date: Feb. 25, 2021

(54) POLISHING PAD

(71) Applicant: NITTA DUPONT INCORPORATED, Osaka (JP)

(72) Inventor: Akira OZEKI, Kyoto (JP)

(21) Appl. No.: 16/960,333

(22) PCT Filed: Jan. 11, 2019
(86) PCT No.: PCT/JP2019/000668

§ 371 Date: Jul. 7, 2020

(30) Foreign Application Priority Data
Jan. 12, 2018 (JP) 2018-003472

(51) Int. Cl. B24B 37/26

(52) U.S. Cl. CPC B24B 37/26

(57) ABSTRACT

The present invention is a polishing pad configured to be capable of polishing a polishing object while rotating with a polishing slurry supplied thereon, wherein the polishing pad includes a polishing layer having a polishing surface capable of polishing the polishing object, and the polishing surface includes a non-contact part formed of at least one of a recess and a through hole extending through the polishing layer, the at least one of the recess and the through hole being arranged on a concentric circle having a radius of a given length and having a center that is a rotation center of the polishing pad during rotation for polishing the polishing object.

### CROSS-REFERENCE TO RELATED APPLICATION

This application claims priority to Japanese Patent Application No. 2018-003472, the disclosure of which is incorporated herein by reference in its entirety.

### FIELD

The present invention relates to a polishing pad for polishing a polishing object such as a semiconductor wafer.

### BACKGROUND

As a method for polishing a polishing object such as a semiconductor wafer, a method using a polishing pad is known (e.g., Patent Literature 1). For example, as shown in FIG. 13, a method, which includes pressing a polishing pad 101 attached to a surface of a surface plate 104 toward the polishing object 102 held by a carrier 103, rotating the carrier 103 and the surface plate 104, and polishing a surface of a polishing object 102 while supplying a polishing slurry onto a central area of the polishing pad 101, is disclosed.

The heat hardly escapes in the central area of the polishing object compared with a peripheral portion surrounding this central area. Thus, according to such a polishing method, the polishing object is likely to have an increased temperature in the central area when the polishing object is polished. Further, since a chemical reaction between the polishing object and the polishing slurry is likely to proceed in an area of the polishing object whose temperature is high, a polishing amount of the central area of the polishing object is increased. Therefore, according to such a method, the surface of the polishing object may not be flattened.

### CITATION LIST

### Patent Literature

Patent Literature 1: JP 1111-347935 A

### SUMMARY

### Technical Problem

In view of the aforementioned conventional problem, it is therefore an object of the present invention to provide a polishing pad used for polishing a polishing object and capable of improving the flatness of a polished surface of the polishing object.

### Solution to Problem

A polishing pad according to the present invention is configured to be capable of polishing a polishing object while rotating with a polishing slurry supplied thereon, wherein the polishing pad includes a polishing layer having a polishing surface capable of polishing the polishing object, and the polishing surface includes a non-contact part formed of at least one of a recess and a through hole extending through the polishing layer, the at least one of the recess and the through hole being arranged on a concentric circle having a radius of a given length and having a center that is a rotation center of the polishing pad during rotation for polishing the polishing object.

In the polishing pad, the at least one of the recess and the through hole extending through the polishing layer may be formed of a plurality of recesses or a plurality of through holes that are arranged on the concentric circle with a distance from each other.

It may be configured such that the polishing surface of the polishing pad has a circular shape or a substantially circular shape, and the at least one of the recess and the through hole extending through the polishing layer includes a first non-contact area that is at least one of a recess and a through hole arranged on a concentric circle that has a radius R1 satisfying a formula below, wherein the radius of the given length is R1 and a length of radius of the polishing pad is r

0<R1≤r/2.

The polishing pad may be configured such that the at least one of the recess and the through hole extending through the polishing layer includes a second non-contact area that is at least one of a recess and a through hole arranged on a concentric circle that has a radius R2 satisfying a formula below, wherein the radius of the given length is R2

R1<R2≤3*r/4.

### BRIEF DESCRIPTION OF DRAWINGS

FIG. 1 is a top view of a polishing pad according to one embodiment of the present invention.

FIG. 2 is a schematic view showing a state in which the polishing pad according to the embodiment and a polishing object are overlapped with each other.

FIG. 3 is a schematic view of the polishing pad according to the embodiment and a polishing object.

FIG. 4 is a graph for explaining an effect produced by the polishing pad according to the embodiment.

FIG. 5 is a graph for explaining another effect produced by the polishing pad according to the embodiment.

FIG. 6 is a top view of a polishing pad according to another embodiment of the present invention.

FIG. 7 is a top view of a polishing pad according to another embodiment of the present invention.

FIG. 8 is a top view of a polishing pad according to another embodiment of the present invention.

FIG. 9 is a top view of a polishing pad according to another embodiment of the present invention.

FIG. 10 is a top view of a polishing pad according to another embodiment of the present invention.

FIG. 11 is a top view of a polishing pad according to another embodiment of the present invention.

FIG. 12 is a top view of a polishing pad according to another embodiment of the present invention.

FIG. 13 is a schematic cross-sectional view showing a state in which a conventional polishing pad and a polishing object are overlapped with each other.

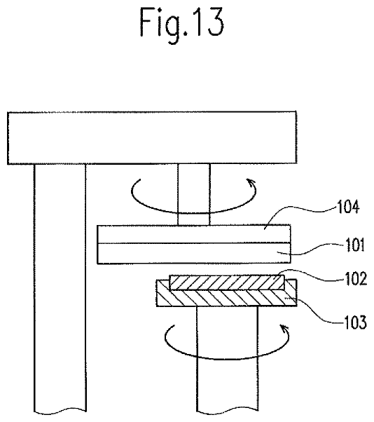

### DESCRIPTION OF EMBODIMENTS

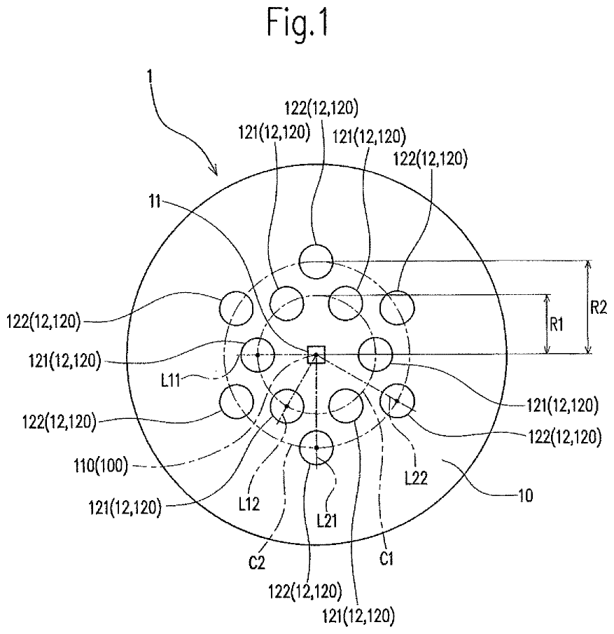

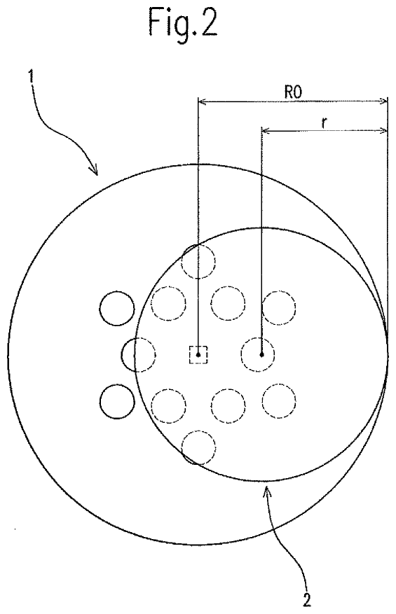

Hereinafter, an embodiment of the polishing pad according to the present invention will be described with reference to FIG. 1 and FIG. 2. The polishing pad according to this embodiment is used for polishing a polishing object (such as a semiconductor wafer) required to have a surface with high flatness. The polishing pad has a polishing surface provided with a non-contact part formed of at least one of a recess and a through hole (i.e., a through hole extending through a polishing layer having the polishing surface). The polishing pad is used to allow the non-contact part to pass the central area of the polishing object so that, even if the heat accumulates in the central area of the polishing object to cause the temperature increase, the polishing amount of the central area of the polishing object is reduced. Thus, the flatness of the polished surface of the polishing object is reliably achieved.

A polishing pad 1 has a disc shape, for example, as shown in FIG. 1. The polishing pad 1 has a polishing layer having a polishing surface 10 capable of polishing a polishing object.

The polishing surface 10 has a circular shape or a substantially circular shape. The polishing surface 10 of this embodiment has a slurry hole 11, which is a through hole for supplying a slurry therethrough, and non-contact parts 12, each of which is formed of a through hole 120 extending through the polishing layer. An area excluding the non-contact parts 12 of the polishing surface 10 has a flat profile.

The slurry hole 11 has a square shape in the direction in which the polishing surface 10 extends. The dimension of each side of the slurry hole is 20 mm, for example.

The non-contact parts 12 are arranged on a concentric circle around a center 100 of the polishing surface 10 and having a radius of a given length. The non-contact parts 12 of this embodiment are formed of a plurality of through holes 120 (e.g., 12 through holes). The through holes 120 are aligned on the concentric circle with a distance from each other. The through holes 120 have a constant diameter and extend through the polishing layer (i.e., through holes having a constant diameter at any positions in the extending direction). Specifically, the through holes 120 have a circular shape in the expanding direction of the polishing surface 10. The through holes 120 have a diameter of 5 mm or more, for example, approximately 50 mm.

Specifically, the through holes 120 form first non-contact parts 121 and second non-contact parts 122 respectively arranged on two concentric circles having different radii around the center 100 of the polishing surface 10. More specifically, the through holes 120 form the first non-contact parts 121 that are 6 through holes arranged on a concentric circle C1 having a radius R1 and the second non-contact parts 122 that are 6 through holes arranged on a concentric circle C2 having a radius R2 larger than the radius R1. The first non-contact parts 121 and the second non-contact parts 122 are distant from each other.

The first non-contact parts 121 are arranged on the concentric circle C1 with a distance from each other. Also, the first non-contact parts 121 are arranged at equal intervals. Specifically, each of the centers of the first non-contact parts 121 arranged at equal intervals lies on the concentric circle C1. More specifically, each of the centers of the first non-contact parts 121 is located between a virtual line L21 connecting the center 100 of the polishing surface 10 and the center of one of the second non-contact parts 122 and a virtual line L22 connecting the center 100 of the polishing surface 10 and the center of an adjacent one of the second non-contact parts 122 (for example, in the center between the virtual lines L21 and L22). The ratio of “the area of the first non-contact parts 121 (i.e., the sum of the areas of the first non-contact parts 121 formed on the polishing surface 10)” to “the circumferential area extending with the concentric circle C1 acting as the centerline of the circumferential area while having a band shape with a width equal to the diameter of the first non-contact parts 121” is 4.4% or more and 70% or less. When a plurality of first non-contact parts 121 are arranged on the concentric circle C1 as the first non-contact parts 121 of this embodiment, the ratio of “the area of the first non-contact parts 121 (i.e., sum of the areas of the first non-contact parts 121 formed on the polishing surface 10)” to “the circumferential area extending with the concentric circle C1 acting as the centerline of the circumferential area while having a band shape with a width equal to the diameter of the first non-contact parts 121” is 8.8% or more and 70% or less.

The second non-contact parts 122 are arranged on the concentric circle C2 with a distance from each other. The second non-contact parts 122 are arranged at equal intervals. Specifically, each of the centers of the second non-contact parts 122 arranged at equal intervals lies on the concentric circle C2. More specifically, each of the centers of the second non-contact parts 122 is located between a virtual line L11 connecting the center 100 of the polishing surface 10 and the center of one of the first non-contact parts 121 and a virtual line L12 connecting the center 100 of the polishing surface 10 and the center of an adjacent one of the first non-contact parts 121 (for example, in the center between the virtual lines L11 and L12). The ratio of “the area of the second non-contact parts 122 (i.e., the sum of the areas of the second non-contact parts 122 formed on the polishing surface 10)” to “the area of the circumferential area extending with the concentric circle C2 acting as the centerline of the circumferential area while having a band shape with a width equal to the diameter of the second non-contact parts 122” is 2.9% or more and 70% or less. When a plurality of second non-contact parts 122 are arranged on the concentric circle C2 as the second non-contact parts 122 of this embodiment, the ratio of “the area of the second non-contact parts 122 (i.e., the sum of the areas of the second non-contact parts 122 formed on the polishing surface 10)” to “the circumferential area extending with the concentric circle C2 acting as the centerline of the circumferential area while having a band shape with a width equal to the diameter of the second non-contact parts 122” is 5.9% or more and 70% or less.

The ratio of “the area of the first non-contact parts 121” to “the circumferential area having a band shape with a uniform width, which encompasses all of the first non-contact parts 121 arranged on the concentric circle C1 including the entirely of the first non-contact part(s) 121 located on the innermost side (the first non-contact part(s) 121 closest to the center of the polishing pad 1) and the entirely of the first non-contact part(s) 121 located on the outermost side (the first non-contact parts 121 farthest from the center of the polishing pad 1)” is greater than the ratio of “the area of through holes 120 arranged on one concentric circle located inside or outside the concentric circle C1 (i.e., the sum of the areas of the through holes 120 arranged on this one concentric circle)” to “the circumferential area having a band shape with a uniform width, which encompasses all of the through holes 120 arranged on this one concentric circle including the entirely of the through hole(s) 120 located on the innermost side and the entirely of the through hole(s) 120” located on the outermost side. In the polishing pad 1 of this embodiment, the first non-contact parts 121 are arranged with the concentric circle C1 acting as the centerline of the first non-contact parts 121 and the first non-contact parts 121 entirely overlap with the band-shaped circular area with its width equal to the diameter of the first non-contact parts 121. The second non-contact parts 122 are arranged with the concentric circle C2 acting as the centerline of the second non-contact parts 122 and the second non-contact parts 122 entirely overlap with the band-shaped circular area with its width equal to the diameter of the second non-contact parts 122. Thus, the ratio of “the area of the first non-contact parts 121” to “the circumferential area having a band shape with its width equal to the diameter of the first non-contact parts 121 with the concentric circle C1 acting as the centerline of the first non-contact parts 121” is greater than the ratio of “the area of the second non-contact parts 122” to “the area of the circumferential area having a band shape with its width equal to the diameter of the second non-contact parts 122 with the concentric circle C2 acting as the centerline of the second non-contact parts 122”.

The areas of the first non-contact parts 121 and the second non-contact parts 122 each are configured to be 70% or less than the corresponding band-shaped circumferential areas with their widths respectively equal to the diameters of the first and second non-contact parts 121 and 122. Thus, the distance between each adjacent two through holes 120 on the same concentric circle C1, C2 can be increased to a distance equivalent to half or more of the radius of the through holes 120. As a result, the durability of the polishing pad 1 and the workability of the polishing pad can be reliably achieved.

The polishing pad 1 of this embodiment is configured to polish a polishing object 2 in a disc shape while partially overlapping with the same as shown in FIG. 2. Specifically, the polishing pad 1 is configured to polish the polishing object 2 in a state where a part of the outer circumferential edge of the polishing pad 1 overlaps with a part of the outer circumferential edge of the polishing object 2.

During the polishing, the polishing pad 1 of this embodiment rotates, while being supplied with a polishing slurry (hereinafter referred to as a slurry). For example, the polishing pad 1 of this embodiment is rotatable because it is directly or indirectly attached to a surface plate that rotates around one point acting as the rotation center. Specifically, the polishing pad 1 and the surface plate are arranged such that a center 110 of the slurry hole 11 (see FIG. 1) coincides with the rotation center of the surface plate at the time of rotation of the polishing pad 1, and thus, the center 110 of the slurry hole 11 coincides with the rotation center of the polishing surface 10 at the time of rotation for polishing the polishing object 2. The center 110 of the slurry hole 11 of this embodiment also coincides with the center 100 of the polishing surface 10. Thus, the polishing surface 10 rotates around the the center 100 as the rotation center when the polishing object 2 is polished. During polishing by the polishing pad 1, the polishing pad 1 and the polishing object 2 rotate in the same direction (e.g., in the counterclockwise direction).

The polishing pad 1 of this embodiment is intended to polish the polishing object 2 having such a dimension that, when the radius of the polishing pad 1 is R0 and the radius of the polishing object 2 is r, the radius R0 of the polishing pad 1 is larger than the radius r of the polishing object 2 (see FIG. 2). Specifically, the polishing pad 1 is intended to polish the polishing object 2 having such a dimension that the radius R0 of the polishing pad 1 is larger than the radius r of the polishing object 2 and smaller than the diameter of the polishing object 2.

At this time (when the radius of the polishing object 2 is r (see FIG. 1)), radius R1 of the concentric circle 1 (see FIG. 2)satisfies the formula below.

0≤R1≤r/2

The first non-contact parts 121 are arranged on the concentric circle C1 so that, as described above, the radius R0 of the polishing pad 1 is larger than the radius r of the polishing object 2 and equal to or smaller than the diameter of the polishing object 2, and a part of the outer circumferential edge of the polishing pad 1 overlaps with a part of the outer circumferential edge of the polishing object 2. When the polishing object 2 is polished in this state, the first non-contact parts 121 pass the polishing object 2.

At this time (when the radius of the polishing object 2 is r (see FIG. 1), radius R2 (see FIG. 2) of the concentric circle C2 satisfies the formula below.

R1<R2≤3*r/4

When the polishing object 2 is polished in the aforementioned state where the radius R0 of the polishing pad 1 is larger than the radius r of the polishing object 2 and equal to or smaller than the diameter of the polishing object 2, and a part of the outer circumferential edge of the polishing pad 1 and a part of the outer circumferential edge of the polishing object 2 overlap with each other, it is possible to reduce the sliding distance of the polishing pad 1 in the inside area of the polishing object 2 (for example, in the area having a radius equal to or smaller than the radius r on the polishing object 2) because the second non-contact parts 122 are arranged on the concentric circle C2.

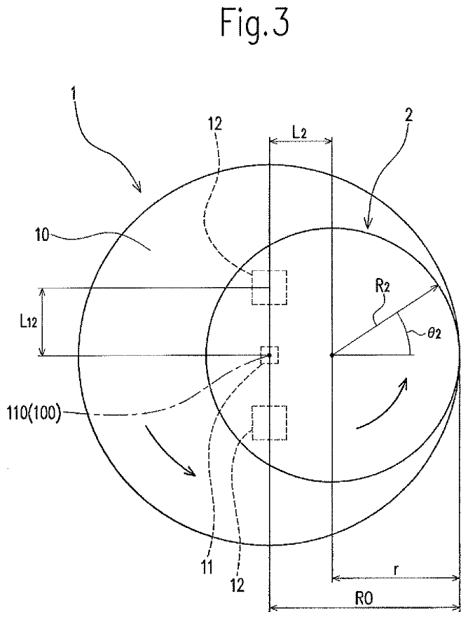

According to the aforementioned polishing pad 1, in the case where the polishing pad 1 is used to allow the concentric circle C1 with the first non-contact parts 121 arranged thereon to pass a central area of the polishing object 2 (for example, a central area including the center of the polishing object 2 and a periphery located outside this center, (i.e., a portion of the polishing object 2 excluding the circumferential edge)), it is possible to reduce the sliding distance of the polishing surface 10 with respect to the central area of the polishing object 2, as compared with the configuration in which the entire polishing surface 10 can contact the polishing object 2. Thus, even if the temperature in the central area of the polishing object 2 is higher than in the other areas, the polishing amount is reduced by the reduction of the frictional heat in the central area of the polishing object 2 due to the sliding of the polishing surface 10 in the central area of the polishing object and the reduction of the sliding distance of the polishing surface 10 in the central area of the polishing object 2, so that the flatness of the polished surface of the polishing object 2 can be improved. The flatness of the polished surface of the polishing object 2 can be evaluated by calculating a polishing amount of the polishing object 2 (hereinafter referred to as a polishing amount) at an optional position (point P) of the polishing object 2 when the polishing object 2 is polished by the polishing pad 1 for a certain period of time. Hereinafter, the calculation method thereof will be described. For example, the polishing pad 1 and the polishing object 2 each have a disc shape as shown in FIG. 3, and the radius R0 of the polishing pad 1 is larger than the radius r of the polishing object 2 and equal to or smaller than the diameter of the polishing object 2. The slurry hole 11 and the through holes 120 are through holes each having a square shape in the direction in which the polishing surface 10 extends. Two through holes 120 are provided and arranged on a concentric circle with a distance from each other. The polishing pad 1 and the polishing object 2 rotate in the same direction (for example, in the counterclockwise direction).

In this case, the Preston's equation is employed as a method of calculating the polishing amount of the polishing object at the point P. In the Preston's equation, the formula below is established when p is the polishing amount of the polishing object, k is Preston's coefficient, ρ(P) is the pressure of the polishing pad 1 applied to the polishing object 2, V(P) is the sliding speed at the point P on the polishing object 2, and t is the polishing time of the polishing object by the polishing pad 1.

p=k*ρ(P)*V(P)*t

According to the Preston' equation, when the pressure ρ(P) of the polishing pad 1 applied to the polishing object 2 is constant (when the pressure ρ(P) does not change with time during the polishing), the polished amount p of the polishing object 2 is proportional to a value obtained by multiplying the polishing time t by the sliding speed V(P) (i.e., an integrated value of the sliding speed V(P) in a certain period of time, hereinafter referred to as the sliding distance SD). As described above, the flatness of the polished surface of the polishing object 2 in the polishing pad 1 of this embodiment can be evaluated using the sliding distance SD and the polishing amount p of the polishing object 2.

When the angular velocity of the polishing pad 1 is referred to as ω₁, the angular velocity of the polishing object 2 is referred to as ω₂, the coordinate of the point P is referred to as (R₂,θ₂), and the distance between the center of the polishing pad 1 (i.e., the center 100 of the polishing surface 10 (i.e, the center 110 of the slurry hole 11)) and the point P is referred to as L₂, the sliding speed V₂ (R₂,θ₂) at the point P is obtained by the formula below.

V₂(R₂,θ₂)={(ω₂²L₂²+2(ω₂—ω₁)ω₁*L₂*R₂*cos θ₂+(ω₂−ω₁)²*R₂}^{1/2}

According to the polishing pad 1 of this embodiment, in the case where the polishing pad 1 is used to allow the concentric circle C1 with the first non-contact parts 121 arranged thereon to pass the central area of the polishing object 2, the interval during which the state where the polishing surface 10 slides on the polishing object 2 is changed to the state where the polishing surface 10 does not slide on the polishing object 2, or vice versa is shorter than the interval in the configuration where only one first non-contact part 121 is provided. Thus, it is possible to suppress unevenness in the polishing conditions, such as the dispersion state of the slurry on the polishing surface 10 and the temperature distribution of the polishing object 2, in the polishing using the polishing pad 1, and to thereby stably perform the polishing.

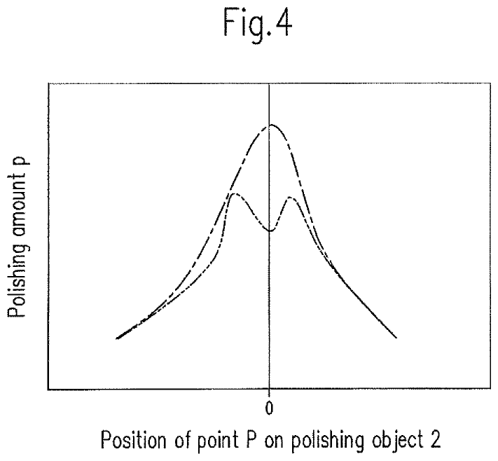

Further, according to the polishing pad 1 of this embodiment, in the case where, for polishing the polishing object 2 having a substantially disc shape and a diameter larger than the radius of the polishing pad 1 and equal to or smaller than the diameter of the polishing pad, the polishing pad 1 is used to allow the concentric circle C1 with the first non-contact parts 121 arranged thereon to pass the central area of the polishing object 2, the entire surface to be polished of the polishing object 2 contacts the polishing pad 1, and the sliding distance of the polishing surface 10 in the central area of the polishing object 2 is reduced. Thus, even if the temperature in the central area of the polishing object 2 is higher than in the other areas, the reduction of the sliding distance of the polishing surface 10 in the central area of the polishing object 2 enables to reduce, for example, the polishing amount p as represented by two-dot chain line in FIG. 4, so that the flatness of the polished surface of the polishing object 2 can be improved. The one-dot chain line in FIG. 4 represents the polishing amount p in the case where the polishing surface 10 does not include the non-contact parts 12.

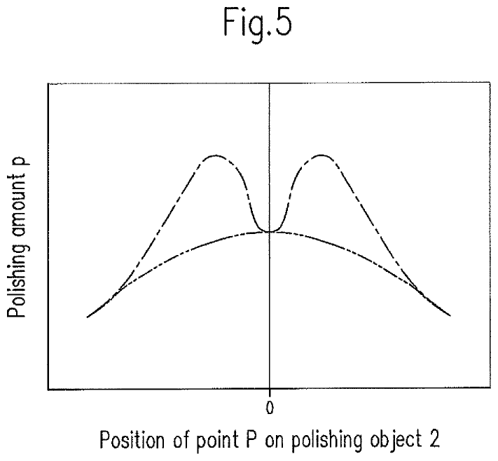

In the configuration of arranging only the first non-contact parts 121 for polishing the polishing object 2 having a substantially disc shape and a diameter larger than the radius of the polishing pad 1 and equal to or smaller than the diameter of the polishing pad 1, when the polishing pad 1 is used to allow the concentric circle C1 with the first non-contact parts 121 arranged thereon to pass the central area of the polishing object 2, the sliding distance of the polishing surface 10 in the central area of the polishing object 2 is reduced, but not reduced in the area outside the central area of the polishing object 2. Thus, the polishing amount p in the area outside the central area of the polishing object remains large as shown by one-dot chain line in FIG. 5, for example. Contrarily, according to the polishing pad 1 of this embodiment, in the case where the polishing pad 1 is used to allow the concentric circle C2 with the second non-contact parts 122 arranged thereon to pass the area outside the central area of the polishing object 2 and allow the concentric circle C1 with the first non-contact parts 121 arranged thereon to pass the central area of the polishing object 2, the sliding distance of the polishing surface 10 is reduced also in the area outside the central area of the polishing object 2. Thus, the reduction of the sliding distance of the polishing surface 10 in the area outside the central area of the polishing object 2 enables the reduction of the polishing amount p, for example, as represented by the two-dot chain line in FIG. 5, so that the flatness of the polished surface of the polishing object 2 can be further improved.

Further, according to the polishing pad 1 of this embodiment, the first non-contact parts 121 and the second non-contact parts 122 are separated from each other so that the polishing can be more stably performed than the continuous arrangement of the first non-contact parts 121 and the second non-contact parts 122.

The polishing pad of the present invention is not limited to the aforementioned embodiment, and it is of course that various modifications can be made without departing from the gist of the present invention. For example, the configuration of a particular embodiment can be added to the configuration of another embodiment, and a part of the configuration of a particular embodiment can be replaced with the configuration of another embodiment. In addition, a part of the configuration of a particular embodiment can be eliminated.

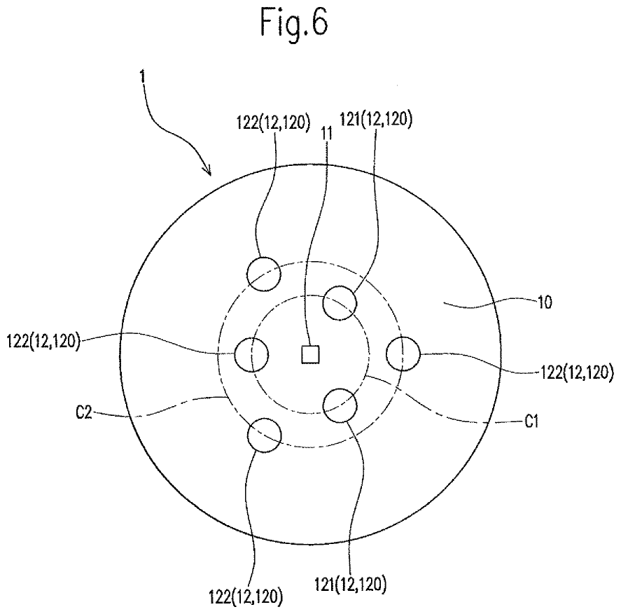

For example, the number of the first non-contact parts 121 and the second non-contact parts 122 are each not limited to 6. For example, as shown in FIG. 6, 3 first non-contact parts 121 and 3 second non-contact parts 122 may be provided in the polishing pad 1. The first non-contact parts 121 are arranged on the concentric circle C1 at equal intervals, and the second non-contact parts 122 are arranged on the concentric circle C2 at equal intervals. Each of the first non-contact parts 121 and the second non-contact parts 122 is a through hole 120 in a circular shape. The diameter of the through hole 120 is, for example, 9% or less of the diameter of the polishing pad 1. Specifically, when the diameter of the polishing pad is 450 mm, the diameter of the through hole 120 is, for example, 40 mm.

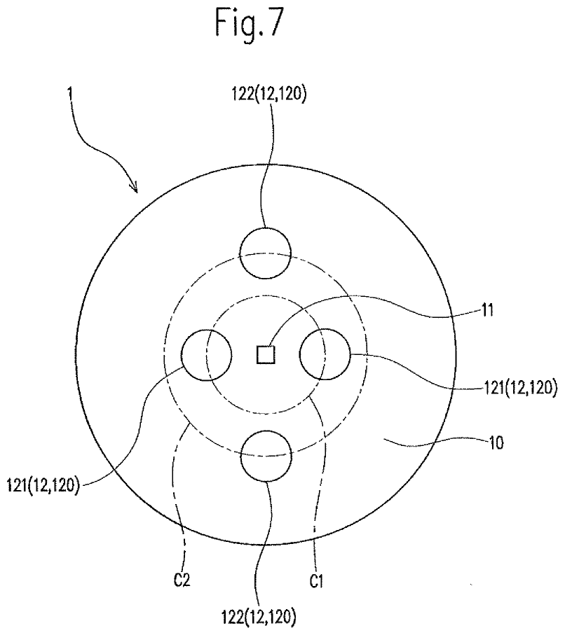

As shown in FIG. 7, 2 first non-contact parts 121 and 2 second non-contact parts 122 may be provided. The first non-contact parts 121 are arranged on the concentric circle C1 at equal intervals, and the second non-contact parts 122 are arranged on the concentric circle C2 at equal intervals. Each of the first non-contact parts 121 and the second non-contact parts 122 is a through hole 120 in a circular shape. The diameter of the through hole 120 is, for example, 13% or less of the diameter of the polishing pad 1. Specifically, when the diameter of the polishing pad 1 is 450 mm, the diameter of the through hole 120 is, for example, 60 mm.

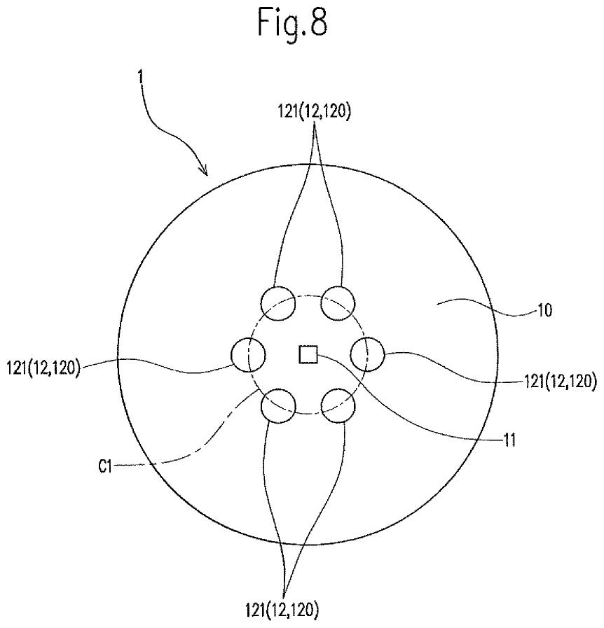

The non-contact parts 12 of this embodiment are formed of both of the first non-contact parts 121 and the second non-contact parts 122, but may be formed of either the first non-contact parts 121 or the second non-contact parts 122. For example, as shown in FIG. 8, the non-contact parts 12 may be formed of 6 through holes 120 (the first non-contact parts 121). The first non-contact parts 121 are arranged on the concentric circle C1 at equal intervals.

In the case where the polishing pad 1 of this configuration is used, the flatness of the polished surface of the polishing object 2 can be improved by providing the non-contact parts 12 in the polishing surface 10.

The polishing pad 1 of the aforementioned embodiment has a disc shape, but may have any shape as long as it can polish the polishing object while rotating, for example, a different shape such as a rectangular plate shape. Also, the polishing surface 10 may have any shape such as a rectangular shape, in addition to a circular shape or a substantially circular shape. Each of the non-contact parts 12 of the aforementioned embodiment is a through hole 120 having a circular shape or a cross shape extending in the direction in which the polishing surface 10 extends, but may be, for example, a circular hole 120 having a different shape such as a triangular shape, a rectangular shape, an arched shape extending in this direction. The diameter of the through hole 120 is constant therethrough, but the diameter of the through hole 120 may be increased or decreased toward. the polishing surface 10 side. Each of the non-contact parts 12 may be a recess provided in the polishing surface 10. Further, both of a recess and a through hole may be arranged in the polishing surface 10, and for example, both of a recess and a through hole may be arranged on one concentric circle.

The polishing pad 1 of the aforementioned embodiment includes one or two concentric circles on which the non-contact parts 12 are arranged, but may include three or more concentric circles. The polishing amount can be more controlled by providing three or more concentric circles.

In the polishing surface 10 of the aforementioned embodiment, a plurality of the non-contact parts 12 are provided, but only one non-contact part 12 may be provided.

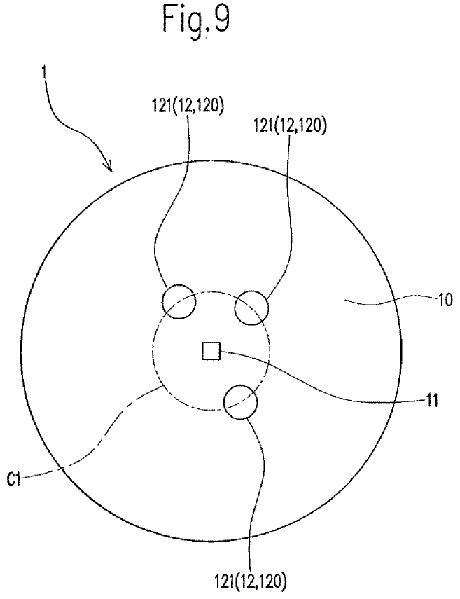

In the polishing surface 10 of the aforementioned embodiment, a plurality of the non-contact parts 12 are arranged respectively on the concentric circles C1, C2 at equal intervals, but the non-contact parts 12 arranged on the concentric circle C1 and the non-contact parts 12 on the concentric circle C2 may be arranged at different intervals. For example, as shown in FIG. 9, the distances between each adjacent two first non-contact parts 121 arranged on the concentric circle C1 may differ from each other. Also in this configuration, in the case where the polishing pad 1 is used to allow the concentric circle C1 with the first non-contact parts 121 arranged thereon to pass the central area of the polishing object 2, the sliding distance of the polishing pad 1 in the central area of the polishing object 2 is reduced by the reduction in the number of times by which the polishing pad 1 contacts the central area of the polishing object 2. Thus, the flatness of the polished surface of the polishing object 2 can be improved, as compared with the configuration where the entire polishing surface 10 contacts the polishing object 2.

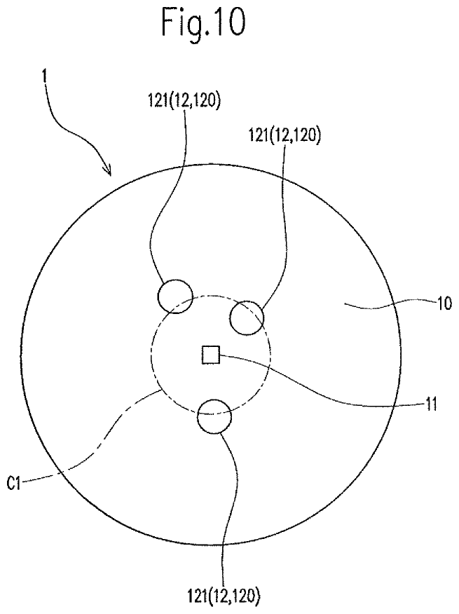

In the polishing surface 10 of the aforementioned embodiment, the center of each of the first non-contact parts 121 and the center of each of the second non-contact parts 122 are arranged respectively on the concentric circle C1 and the concentric circle C2. However, each of the first non-contact parts 121 may be arranged at a position at which the center of the non-contact part 121 is displaced from the concentric circle C1 (i.e., inside or outside the concentric circle C1) as shown in FIG. 10, provided that the first non-contact part 121 is arranged at least partly on the concentric circle C1. In this configuration, the area in which the sliding distance of the polishing pad on the polishing object 2 is reduced can be adjusted by arranging each of the first non-contact part 121 to have its center arranged at a position displaced from the concentric circle C1.

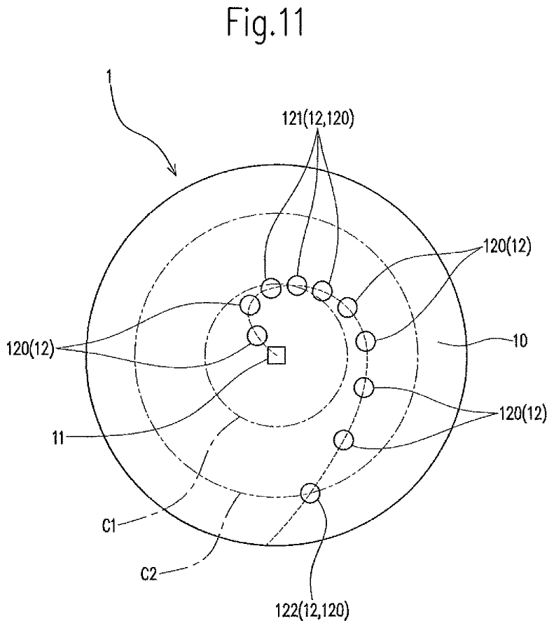

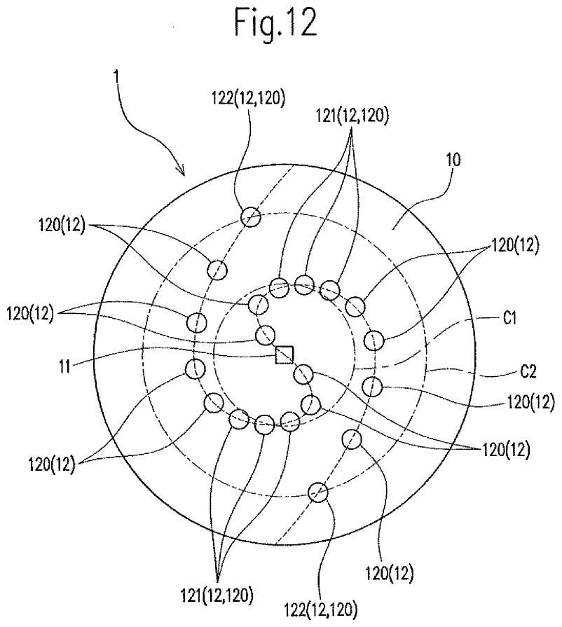

In addition to the first non-contact parts 121 and the second non-contact parts 122, the through holes 120 or the recesses not arranged on the concentric circle C1 or the concentric circle C2 may be provided in the polishing surface 10. Specifically, as shown in FIG. 11, the through holes 120 (for example, through holes including the first non-contact parts 121 and the second non-contact parts 122) may be arranged on one spiral (for example, on a spiral extending from the center of the polishing pad 1). Also, as shown in FIG. 12, the through holes 120 (for example, through holes 120 including the first non-contact parts 121 and the second non-contact parts 122) may be arranged on a plurality of spirals (for example, on two spirals). In this configuration, the ratio of “the area of the first non-contact parts 121” to “the circumferential area having a band shape with a uniform width, which encompasses all of the first non-contact parts arranged on the concentric circle C1 including the entirely of the first non-contact part(s) 121 located on the innermost side (the first non-contact part(s) 121 closest to the center of the polishing pad 1) and the entirely of the first non-contact part(s) located on the outermost side (the first non-contact parts 121 farthest from the center of the polishing pad 1)” is greater than the ratio of “the area of through holes 120 arranged on one concentric circle located inside or outside the concentric circle C1” to “the circumferential area having a band shape with a uniform width, which encompasses all of the through holes 120 arranged on this one concentric circle including the entirely of the through hole(s) 120 located on the innermost side and the entirely of the through hole(s) 120 located on the outermost side”.

Also in this configuration, in the case where the polishing pad 1 is used to allow the concentric circle C1 with the first non-contact parts 121 arranged thereon to pass the central area of the polishing object 2, the sliding distance of the polishing pad 1 in the central area of the polishing object 2 is reduced by the reduction in the number of times by which the polishing pad 1 contacts the central area of the polishing object 2. Thus, the flatness of the polished surface of the polishing object 2 can be improved, as compared with the configuration where the entire polishing surface 10 contacts the polishing object 2. Further, in the case where the polishing pad 1 is used to allow the concentric circle C2 with the second non-contact parts 122 arranged thereon to pass the area outside the central area of the polishing object 2 and allow the concentric circle C1 with the first non-contact parts 121 arranged thereon to pass the central area of the polishing object 2, the sliding distance of the polishing surface 10 is reduced also in the area outside the central area of the polishing object 2. Thus, the reduction of the sliding distance of the polishing surface 10 in the area outside the central area of the polishing object 2 enables the flatness of the polished surface of the polishing object 2 to be further improved. Moreover, the first non-contact parts 121 and the second non-contact parts 122 are allowed to easily pass the center area of the polishing object 2 by being arranged on the spiral, so that the area in which the sliding distance of the polishing pad 1 on the polishing object 2 can be adjusted.

Further, lattice-shaped grooves or grooves extending radially from the center 100 of the polishing surface 10 may be formed on the entire polishing surface 10. This arrangement allows the slurry to more evenly spread on the entire polishing surface 10.

The slurry hole 11 is formed in the polishing surface 10 of the aforementioned embodiment to supply the slurry to the polishing surface 10 via the slurry hole 11, but may be formed without the slurry hole 11 so that the slurry is directly supplied to the polishing surface 10.

As described above, according to the present invention, it is possible to provide a polishing pad that is used for polishing a polishing object and can improve the flatness of a polished surface.

A polishing pad according to the present invention is configured to be capable of polishing a polishing object while rotating with a polishing slurry supplied thereon, wherein the polishing pad includes a polishing layer having a polishing surface capable of polishing the polishing object, and the polishing surface includes a non-contact part formed of at least one of a recess and a through hole extending through the polishing layer, the at least one of the recess and the through hole being arranged on a concentric circle having a radius of a given length and having a center that is a rotation center of the polishing pad during rotation for polishing the polishing object.

According to this configuration, in the case where the polishing pad is used to allow the concentric circle with the non-contact part arranged thereon to pass a central area of the polishing object, the sliding distance of the polishing object on the polishing surface in the central area is reduced, as compared with the configuration where the entire polishing surface can contact the polishing object. Thus, even if the temperature in the central area of the polishing object is higher than the temperature in the other areas, the sliding distance of the polishing surface in the central area of the polishing object is reduced so that the frictional heat due to the sliding of the polishing surface on the central area, and the polishing amount due to the sliding distance are reduced. Thus, the flatness of the polished surface of the polishing object can be improved.

In the polishing pad, the at least one of the recess and the through hole extending through the polishing layer may be formed of a plurality of recesses or a plurality of through holes that are arranged on the concentric circle with a distance from each other.

According to this configuration, in the case where the polishing pad is used to allow the concentric circle with the non-contact parts arranged thereon to pass the central area of the polishing object, the interval during which the state where the polishing surface slides on the polishing object is changed to the state where the polishing surface does not slide on the polishing object, or vice versa is shorter than the interval in the configuration where only one first non-contact part is provided. Thus, it is possible to suppress unevenness in the polishing conditions, such as the dispersion state of the slurry on the polishing surface and the temperature distribution of the polishing object in the polishing using the polishing pad, and to thereby stably perform the polishing.

It may be configured such that the polishing surface of the polishing pad has a circular shape or a substantially circular shape, and the at least one of the recess and the through hole extending through the polishing layer includes a first non-contact area that is at least one of a recess and a through hole arranged on a concentric circle that has a radius R1 satisfying a formula below, wherein the radius of the given length is R1 and a length of radius of the polishing pad is r

0<R1≤r/2.

According to this configuration, in the case where, for polishing a polishing object having a substantially disc shape and a diameter larger than the radius of the polishing pad and equal to or smaller than the diameter of the polishing pad, the polishing pad is used to allow the concentric circle with the first non-contact parts arranged thereon to pass the central area of the polishing object, the entire surface to be polished of the polishing object contacts the polishing surface, and the sliding distance of the polishing surface in the central area of the polishing object is reduced. Thus, even if the temperature in the central area of the polishing object is higher than in the other area, the reduction of the sliding distance of the polishing surface in the central area of the polishing object enables to reduce the polishing amount, so that the flatness of the polished surface can be improved.

The polishing pad may be configured such that the at least one of the recess and the through hole extending through the polishing layer includes a second non-contact area that is at least one of a recess and a through hole arranged on a concentric circle that has a radius R2 satisfying a formula below, wherein the radius of the given length is R2

R1<R2≤3*r/4.

In the configuration of arranging only the first non-contact parts, for polishing the polishing object having a substantially disc shape and a diameter larger than the radius of the polishing pad and equal to or smaller than the diameter of the polishing pad, when the polishing pad is used to allow the concentric circle with the first non-contact parts arranged thereon to pass the central area of the polishing object, the sliding distance of the polishing surface in the central area of the polishing object is reduced, but not reduced in the area outside the central area of the polishing object. Thus, the polishing amount in the area outside the central area of the polishing object remains larger than in the central area of the polishing object due to the difference in the sliding distance. On the other hand, according to this configuration, in the case where the polishing pad is used to allow the concentric circle with the first non-contact parts arranged thereon to pass the central area of the polishing object, and allow the concentric circle with the second non-contact parts arranged thereon to pass the area outside the central area of the polishing object, the sliding distance of the polishing surface in the area outside the central area of the polishing object is also reduced. Thus, the reduction of the sliding distance of the polishing surface in the area outside the central area of the polishing object enables the reduction of the polishing amount, so that the flatness of the polished surface of the polishing object can be further improved.

### REFERENCE SIGNS LIST

1, 101: Polishing pad
10: Polishing surface
100: Center
11: Slurry hole
110: Center
12: Non-contact part
120: Through hole
121: First non-contact part
122: Second non-contact part
102: Polishing object
103: Carrier
104: Surface plate
C1, C2: Concentric circle
R0, R1, R2, r: Radius

1. A polishing pad configured to be capable of polishing a polishing object while rotating with a polishing slurry supplied thereon, wherein
the polishing pad comprises a polishing layer having a polishing surface capable of polishing the polishing object, and
the polishing surface comprises a non-contact part formed of at least one of a recess and a through hole extending through the polishing layer, the at least one of the recess and the through hole being arranged on a concentric circle having a radius of a given length and having a center that is a rotation center of the polishing pad during rotation for polishing the polishing object.

2. The polishing pad according to claim 1, wherein,
the at least one of the recess and the through hole extending through the polishing layer is formed of a plurality of recesses or a plurality of through holes that are arranged on the concentric circle with a distance from each other.

3. The polishing pad according to claim 2, wherein
the polishing surface of the polishing pad has a circular shape or a substantially circular shape, and the at least one of the recess and the through hole extending through the polishing layer comprises a first non-contact area that is at least one of a recess and a through hole arranged on a concentric circle that has a radius R1 satisfying a formula below, wherein the radius of the given length is R1 and a length of radius of the polishing pad is r
0<R1≤r/2.

4. The polishing pad according to claim 3, wherein
the at least one of the recess and the through hole extending through the polishing layer comprises a second non-contact area that is at least one of a recess and a through hole arranged on a concentric circle that has a radius R2 satisfying a formula below, wherein the radius of the given length is R2
R1<R2≤3*r/4.
